(19) United States
(12) Patent Application Publication
(10) Pub. No.: US 2025/0273458 A1
(43) Pub. Date: Aug. 28, 2025

(54) METHODS FOR FORMING SEMICONDUCTOR STRUCTURES COMPRISING HAFNIUM ZIRCONIUM OXIDE LAYERS AND METAL OXIDE LAYERS, AND ASSOCIATED STRUCTURES, AND SYSTEMS

(71) Applicant: ASM IP Holding B.V., Almere (NL)

(72) Inventors: Charles Dezelah, Helsinki (FI); Jerome Innocent, Bristol (GB); Matthew Surman, Helsinki (FI); Lorenzo Bottiglieri, Phoenix, AZ (US); Alessandra Leonhardt, Sipoo (FI)

(21) Appl. No.: 19/062,988

(22) Filed: Feb. 25, 2025

Related U.S. Application Data
(60) Provisional application No. 63/557,680, filed on Feb. 26, 2024.

(51) Int. Cl. H01L 21/02; C23C 16/40; C23C 16/44; C23C 16/455; C23C 16/56

(52) U.S. Cl. CPC H01L 21/0228; C23C 16/405; C23C 16/4408; C23C 16/45553; C23C 16/56; H01L 21/02181; H01L 21/02189

(57) ABSTRACT

The technology of the present disclosure relates to the field of capacitor devices. More particularly, methods for forming semiconductor structures including hafnium zirconium oxide (HZO) layers are disclosed. The methods include manufacturing a semiconductor structure by, providing a substrate, and forming a HZO layer thereon by cyclical deposition processes. Systems for forming hafnium zirconium oxide layers are further disclosed, as well as semiconductor structures including HZO layers.

### CROSS-REFERENCE TO RELATED APPLICATION(S)

This Application claims the benefit of U.S. Provisional Application 63/557,680 filed on Feb. 26, 2024, the entire contents of which are incorporated herein by reference.

### FIELD

The present disclosure generally relates to the field of semiconductor devices. More particularly, the present disclosure generally relates to semiconductor structures comprising a high-κ layer, which comprises a hafnium zirconium oxide (HZO) material, and a method for producing the same.

### BACKGROUND

Capacitors are electronic components used to store and regulate electrical energy by accumulating electric charges on two closely spaced surfaces which are insulated from each other. Typically, capacitors are components widely used as parts of electrical circuits in many common electrical devices and are designed with specific capacitance values and voltage ratings to suit the requirements of various applications. Most capacitors contain at least two electrical conductors which serve as the electrodes of the capacitor and are separated by an insulating layer. These structures are also referred to as Metal-Insulator-Metal capacitors (MIM CAPS). The nonconducting insulator or dielectric acts to increase the capacitor's charge capacity. An ideal capacitor is characterized by a constant capacitance C with voltage. The capacitance between the two conductors is a function of the geometry or surface area of the conductors and the distance between the two conductors, and the permittivity of the isolating material between them. In a capacitor, the highest capacitance is achieved with a high permittivity dielectric material, large plate area and a small separation between the plates. The relative permittivity is an essential parameter when designing capacitors. If a material with a high relative permittivity is placed in an electric field, the magnitude of that field will be measurably reduced within the volume of the dielectric. This fact is commonly used to increase the capacitance of a particular capacitor design.

Next generation MIM CAPS, for both logic and memory applications, desire a high dielectric constant value (κ), while having a linear Capacitance Voltage (CV) characteristic. A high dielectric constant value and high capacitance density can be achieved by using a ferroelectric/antiferroelectric Hafnium Zirconium Oxide (HZO) layer resulting in a dielectric constant value κ above 40 and while experiencing low leakage. However, charges trapped in the capacitor may get lost over time, thereby losing information stored in the capacitor and increasing the electricity consumption of the capacitor. Hence, there is a need for capacitors and structures for use in capacitors that store information longer and/or consume less energy.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure relates to a method for manufacturing a semiconductor structure, the method including the steps of: a) providing a substrate into a reaction chamber, b) executing one or more cycles, a cycle comprising: a hafnium precursor pulse, wherein at least a part of the substrate is contacted with one or more hafnium precursors by introducing the one or more hafnium precursors into the reaction chamber, a zirconium precursor pulse, wherein at least a part of the substrate is contacted with one or more zirconium precursors by introducing the one or more zirconium precursors in the reaction chamber, an oxygen reactant pulse, wherein at least a part of the substrate is contacted with one or more oxygen reactants by introducing the one or more oxygen reactants in the reaction chamber, and a dopant precursor pulse, wherein at least a part of the substrate is contacted with one or more dopant precursors by introducing the one or more dopant precursors in the reaction chamber, thereby forming a doped hafnium zirconium oxide layer. In such a method, the substrate includes a metal oxide surface layer, and/or the method further comprises the step of forming a metal oxide top layer on the doped hafnium zirconium oxide layer, thereby forming a layered doped hafnium zirconium oxide structure, the metal oxide surface layer and/or the metal oxide top layer being in direct contact with the doped hafnium zirconium oxide layer.

In some embodiments, a metal (Mⁱ) in the metal oxide surface layer and/or the metal oxide top layer is at a highest initial oxidation state i, and wherein the direct contact with the doped hafnium zirconium oxide layer provides that oxygen is transferred from the metal oxide surface layer and/or the metal oxide top layer to the doped hafnium zirconium oxide layer, thereby lowering the oxidation state of the metal (M^{s}) to a subsequent oxidation state(s), wherein the highest initial oxidation state (i) of the metal in the metal oxide surface layer and/or the metal oxide top layer, and the subsequent oxidation state(s) of the metal are stable oxidation states of the metal, and i>s.

In some embodiments, the doped hafnium zirconium oxide layer is formed at a temperature of at least 300° C. to at most 400° C.

In some embodiments, the pressure in the reaction chamber is between about 0.1 Torr and about 100 Torr.

In some embodiments, the oxygen reactant pulse is carried out after each hafnium precursor pulse and/or after each zirconium precursor pulse.

In some embodiments, the dopant precursor pulse is carried out after the hafnium precursor pulse without any intervening oxygen reactant pulse.

In some embodiments, the dopant precursor pulse is carried out after the zirconium precursor pulse without any intervening oxygen reactant pulse.

In some embodiments, the hafnium precursor pulse, the zirconium precursor pulse, the oxygen reactant pulse, and/or the dopant precursor pulse comprises a plurality of micropulses.

In some embodiments, the method further comprises a post-annealing step.

In some embodiments, the metal M in the metal oxide surface layer and/or the metal oxide top layer is selected from the group consisting of Sn, Ce, Cu, Co, Ge, V, Nb, Ta, Cr, Mo, W, Mn, Fe, Ru, Rh, Ir, Pd, Pt, In, and Pb.

In some embodiments, the metal M in the metal oxide surface layer and/or the metal oxide top layer is selected from the group consisting of Sn, Ce, Cu, Co, and Ge. In some embodiments, the highest initial oxidation state i is at least +2.

In some embodiments, the difference between the highest initial oxidation state (i) and the subsequent oxidation state(s) is at least 1.

In some embodiments, the subsequent oxidation state(s) of the metal is higher than 0.

In some embodiments, the metal oxide surface layer and/or the metal oxide top layer is selected from the group consisting of: SnO₂, wherein the highest initial oxidation state (i) of the Sn in the oxide is +4, CeO₂, wherein the highest initial oxidation state (i) of the Ce in the oxide is +4, CuO, wherein the highest initial oxidation state (i) of the Cu in the oxide is +2, Co₂O₃, wherein the highest initial oxidation state (i) of the Co in the oxide is +3, Co₃O₄, wherein the highest initial oxidation state (i) of the Co in the oxide is +3, GeO₂, wherein the highest initial oxidation state (i) of the Ge in the oxide is +4.

In some embodiments, the method is an atomic layer deposition (ALD) method.

In some embodiments, the layered doped hafnium zirconium oxide structure is formed without any intervening vacuum break.

In some embodiments, the dopant precursor comprises a dopant element selected from the group consisting of Mn, Bi, Sr, B, N, Li, V, S, Sc, P, N, Ni, Ga, Mg, Cr, Sn, Sb, La, Y, Mo, and Al.

In some embodiments, the layered doped hafnium zirconium oxide structure is characterized by having a thickness of at least 2.0 nm to at most 30.0 nm.

An aspect of the present disclosure relates to a system comprising: a reaction chamber constructed and arranged to hold a substrate, a hafnium precursor vessel constructed and arranged to contain and evaporate one or more hafnium precursor, a zirconium precursor vessel constructed and arranged to contain and evaporate one or more zirconium precursor, an oxygen reactant vessel constructed and arranged to contain and evaporate an oxygen reactant, a dopant precursor vessel constructed and arranged to contain and evaporate a dopant precursor, a metal precursor vessel constructed and arranged to contain and evaporate a metal precursor, and a controller. In such a system, the controller is configured to control the flow of the hafnium precursor, the zirconium precursor, the oxygen reactant, the dopant precursor, and the metal precursor, into the reaction chamber, thereby forming a layered doped hafnium zirconium oxide structure on the substrate.

### BRIEF DESCRIPTION OF DRAWINGS

A more complete understanding of exemplary embodiments of the present disclosure can be derived by referring to the detailed description and claims when considered in connection with the following illustrative figures.

FIGS. 1A-C illustrate methods for forming a semiconductor structure in accordance with one or more embodiments.

FIGS. 2-4 illustrate cross-sectional views of (doped) HZO layered structures in accordance with one or more embodiments.

FIGS. 5-7 illustrate cross-sectional views of MIM capacitors in accordance with one or more embodiments.

FIG. 8 illustrates a system for forming a semiconductor structure in accordance with one or more embodiments.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of various aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements, or method steps. The terms “comprising”, “comprises” and “comprised of” when referring to recited members, elements or method steps also include embodiments which “consist of” the recited members, elements, or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may, in some cases, depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula-CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment. When the suffix “ene” is used in conjunction with an alkyl group, i.e., “alkylene,” this is intended to mean the alkyl group as defined herein having two single bonds as points of attachment to other groups. As used herein, the term “alkylene” also referred as “alkanediyl,” by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3- methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C₃₋₂₀alkenyl groups are ethenyl, 2-propenyl, 2-butenyl, 3-butenyl, 2-pentenyl and its isomers, 2-hexenyl and its isomers, 2,4-pentadienyl, and the like.

The term “cycloalkyl”, as a group or part of a group, refers to a cyclic alkyl group, that is a monovalent, saturated, hydrocarbyl group having 1 or more cyclic structure, and comprising from 3 to 20 carbon atoms, more preferably from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged, and/or joined through one or more spiro atoms. When a subscript is used herein following a carbon atom, the subscript refers to the number of carbon atoms that the named group may contain. For example, the term “C₃₋₂₀cycloalkyl”, a cyclic alkyl group comprising from 3 to 20 carbon atoms. For example, the term “C₃₋₁₀cycloalkyl”, a cyclic alkyl group comprising from 3 to 10 carbon atoms. For example, the term “C₃₋₈cycloalkyl”, a cyclic alkyl group comprising from 3 to 8 carbon atoms. For example, the term “C₃₋₆cycloalkyl”, a cyclic alkyl group comprising from 3 to 6 carbon atoms. Examples of C₃₋₁₂cycloalkyl groups include but are not limited to adamantly, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (15,4S)-norbornan-2-yl, (1R,4S)-norbornan-2-yl. When the suffix “ene” is used in conjunction with a cycloalkyl group, i.e., cycloalkylene, this is intended to mean the cycloalkyl group as defined herein having two single bonds as points of attachment to other groups. Non-limiting examples of “cycloalkylene” include 1,2-cyclopropylene, 1,1-cyclopropylene, 1,1-cyclobutylene, 1,2-cyclobutylene, 1,3-cyclopentylene, 1,1-cyclopentylene, and 1,4-cyclohexylene.

Where an alkylene or cycloalkylene group is present, connectivity to the molecular structure of which it forms part may be through a common carbon atom or different carbon atom. To illustrate this applying the asterisk nomenclature of this disclosure, a C₃alkylene group may be for example *—CH₂CH₂CH₂—*, *—CH(—CH₂CH₃)—* or *—CH₂CH(—CH₃)—*. Likewise, a C₃cycloalkylene group may be:

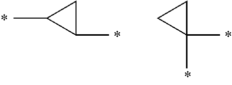

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as '1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

The term “alkoxy” or “alkyloxy,” as a group or part of a group, refers to a group having the formula —OR^{b} wherein R^{b} is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

The term “cycloalkoxy,” as a group or part of a group, refers to a group having the formula —OR^{c} wherein R^{c} is cycloalkyl as defined herein above.

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as '1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

The term “arylalkyl”, as a group or part of a group, means an alkyl as defined herein, wherein at least one hydrogen atom is replaced by at least one aryl as defined herein. Non-limiting examples of arylalkyl group include benzyl, phenethyl, dibenzylmethyl, methylphenylmethyl, 3-(2-naphthyl)-butyl, and the like.

The term “alkylaryl” as a group or part of a group, means an aryl as defined herein wherein at least one hydrogen atom is replaced by at least one alkyl as defined herein. Non-limiting example of alkylaryl group include p-CH₃—R^{d}—, wherein R^{d} is aryl as defined herein above.

The term “heteroalkyl” as a group or part of a group, refers to an acyclic alkyl wherein one or more carbon atoms are replaced by at least one heteroatom selected from the group comprising O, Si, S, B, and P, with the proviso that the chain may not contain two adjacent heteroatoms. This means that one or more —CH₃ of the acyclic alkyl can be replaced by —OH for example and/or that one or more —CR₂— of the acyclic alkyl can be replaced by O, Si, S, B, and P.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some embodiments, the term “precursor” can refer to a compound that participates in the chemical reaction that produces another compound, particularly a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

In this disclosure, the following abbreviations of chemical structures are used: Cp stands for cyclopentadienyl, Me stands for methyl; Et stands for ethyl; nPr stands for n-propyl; nBu stands for n-butyl; tBu stands for t-butyl; acac stands for acetylacetonate.

In general, the technology disclosed herein relates to the field of semiconductor devices, and more specifically to a method for forming a semiconductor structure, preferably comprising a high dielectric constant layer (i.e., a high-κ layer), used in the production of electronic components such as microprocessors, integrated circuit chips, memory chips, and the like. An important step of the semiconductor structure formation referred to herein, can comprise the formation of a film comprising a metal and nitrogen, e.g. a metal nitride film, or a layer on an underlying insulating material, such as a high-k dielectric (or gate dielectric) or silicon oxide (or gate oxide). Advantageously, the embodiments of the present disclosure enable at least partial quenching of oxygen vacancies, preferably interfacial oxygen vacancies, in a high-κ layer, like a HZO layer and/or doped HZO layer. Hence, the methods of the present disclosure can improve the quality of a high-κ layer, preferably a HZO layer and/or doped HZO layer. This may reduce the loss of charges stored/trapped in the layer, which can reduce the power consumption of a semiconductor device comprising such a layer and/or increase the time the charges/signal can be stored in the layer.

Various embodiments of the present disclosure may disfavor (the formation of) a monoclinic phase in a HZO layer, and preferably favors the HZO layer to comprise orthorhombic and/or tetragonal phase. Hence, the embodiments of the present disclosure may improve the ferroelectric properties of a highκ layer, preferably a HZO layer.

As set forth in more detail below, various embodiments of the present disclosure relate to a method for manufacturing a semiconductor structure, comprising the steps of: a) providing a substrate into a reaction chamber; b) forming a HZO layer, preferably a doped hafnium zirconium oxide (HZO) layer; preferably by executing one or more cycles, a cycle comprising: i. a hafnium precursor pulse, wherein at least a part of the substrate is contacted with one or more hafnium precursors by introducing the one or more hafnium precursors in the reaction chamber; ii. a zirconium precursor pulse, wherein at least a part of the substrate is contacted with one or more zirconium precursors by introducing the one or more zirconium precursors in the reaction chamber; iii. an oxygen reactant pulse, wherein at least a part of the substrate is contacted with one or more oxygen reactants by introducing the one or more oxygen reactants in the reaction chamber; and iv. optionally, a dopant precursor pulse, wherein at least a part of the substrate is contacted with one or more dopant precursors by introducing the one or more dopant precursors in the reaction chamber, thereby forming a doped hafnium zirconium oxide (HZO) layer; wherein the substrate comprises a Metal Oxide (MO) surface layer, and/or wherein the method further comprises the step of forming a Metal Oxide (MO) top layer on the HZO layer, preferably the doped HZO layer, thereby forming a layered HZO structure, preferably forming a layered doped HZO structure; and, preferably, wherein the MO surface layer and/or the MO top layer being in direct contact with the HZO layer, preferably the doped HZO layer.

As used herein, the terms “semiconductor structure” or “semiconductor device” refer to an electronic component that relies on the electronic properties of a semiconductor material for its function. The electrical conductivity of a semiconductor falls between that of a conductor (e.g., copper) and an insulator (e.g., soda-lime silica glass). The herein disclosed method can be used to, for example, form complementary metal-oxide-semiconductor (CMOS) devices, or portions of such devices. However, unless noted otherwise, the disclosure is not necessarily limited to such examples.

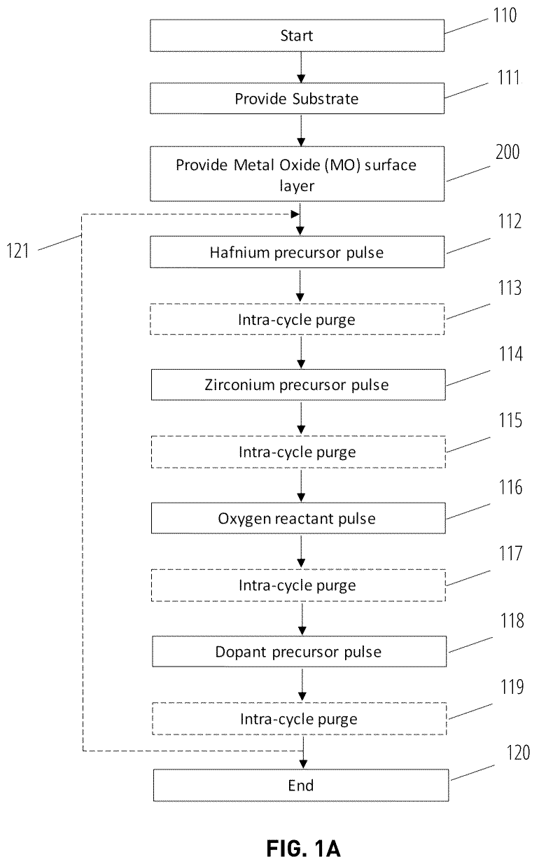

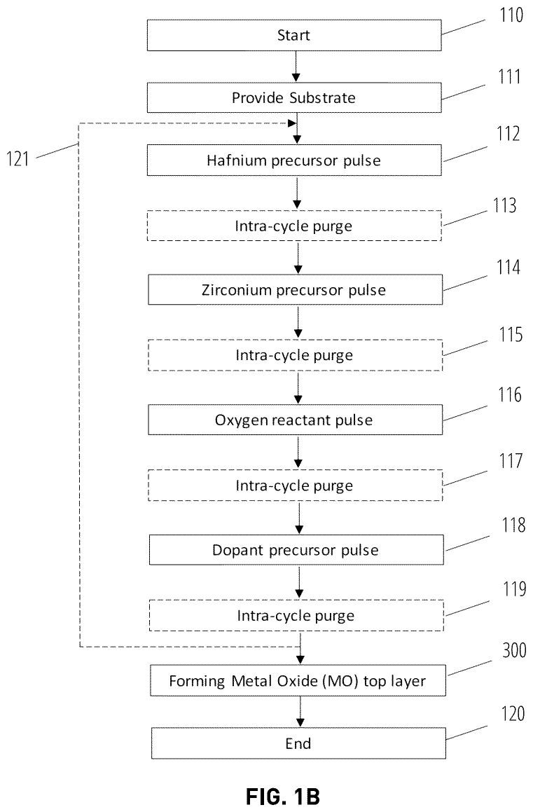

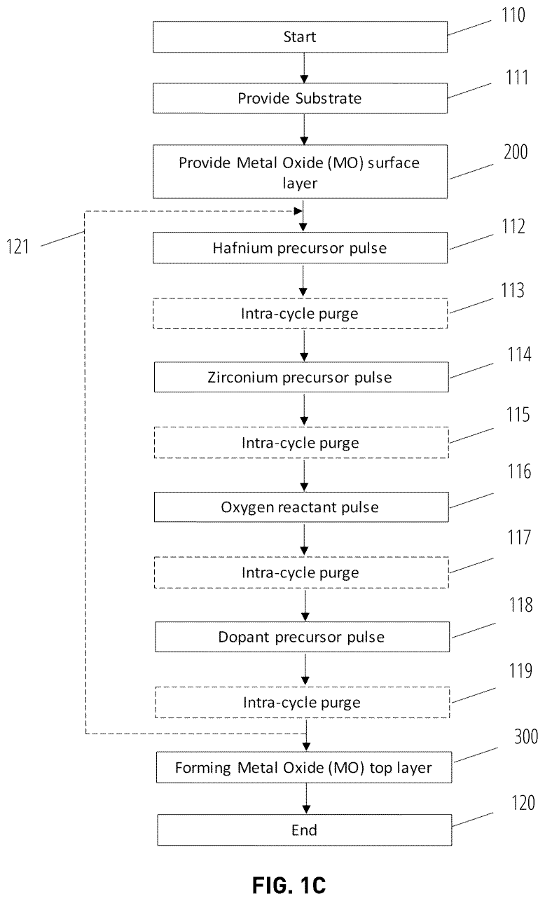

FIG. 1A, FIG. 1B, and FIG. 1C, each describe an exemplary embodiment of the methods of the disclosure for forming a semiconductor structure. Each method starts (110) with providing a substrate in a reaction chamber (111). In the embodiments of FIG. 1A and FIG. 1C, a metal oxide (MO) surface layer is provided (200) on the substrate. The methods further comprise a cyclical deposition process. In various the cyclical deposition process comprises, contacting at least a part of the substrate with a hafnium precursor within a hafnium precursor pulse (112). Optionally, the reaction chamber is purged (113) after the hafnium precursor pulse (112). The cyclical deposition process may further comprise, providing a zirconium precursor to the reaction chamber in a zirconium precursor pulse (114). Optionally, the reaction chamber can be purged (115) after the zirconium precursor pulse. Further, the cyclical deposition process can comprise, providing an oxygen reactant pulse (116) to the reaction chamber. Optionally, the reaction chamber can be purged (117) after the oxygen reactant pulse. The cyclical deposition process can further comprise, providing a dopant precursor to the reaction chamber in a dopant precursor pulse (118). Optionally, the reaction chamber can be purged (119) after the dopant precursor pulse. The hafnium precursor pulse (112), the zirconium precursor pulse (114), the oxygen reactant pulse (116), the dopant precursor pulse (118), and the optional purges (113, 115, 117, 119) can be repeated (121) any number of times to obtain a doped HZO layer having a desired thickness. When a doped HZO containing layer having a desired thickness has been deposited, the method of FIG. 1A ends (120). Whereas in the methods of FIG. 1B and FIG. 1C, a metal oxide (MO) top layer is formed (300) on the surface of the HZO layer, thereafter also these methods end (120). Once the method has ended, the substrate can, for example, be subjected to additional processes to form a device structure and/or device.

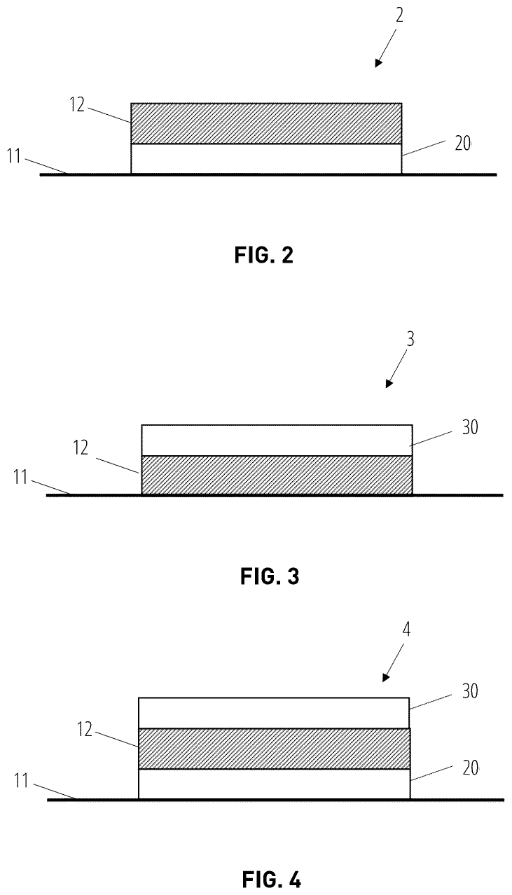

FIG. 2 illustrates a cross-sectional view of a (doped) HZO layered structure (2) obtained by the methods disclosed herein. In this embodiment, the substrate (11) supports a metal oxide (MO) surface layer (20), which is in direct contact with a (doped) HZO layer (12).

FIG. 3 illustrates a cross-sectional view of a (doped) HZO layered structure (3) obtained by the methods disclosed herein. In this embodiment, the substrate (11) supports a (doped) HZO layer (12) which is in direct contact with a metal oxide (MO) top layer (30).

FIG. 4 illustrates a cross-sectional view of a (doped) HZO layered structure (4) obtained by the methods disclosed herein. In this embodiment, the substrate (11) supports a metal oxide (MO) surface layer (20), which is in direct contact with a (doped) HZO layer (12), which again is in direct contact with a metal oxide (MO) top layer (30).

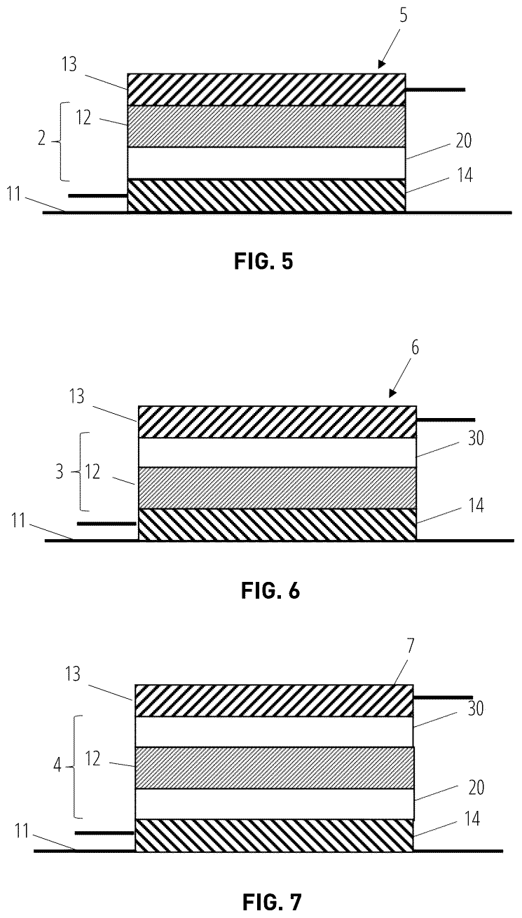

FIG. 5 illustrates a cross-sectional view of a MIM capacitor (5), including the HZO layered structure (2) of FIG. 2, and comprising a metal oxide (MO) surface layer (20), which is in direct contact with a (doped) HZO layer (12). The layered structure (2) is placed between two metal layers which function as electrodes (13, 14). The MIM capacitor (5) is supported on a support (11).

FIG. 6 illustrates a cross-sectional view of a MIM capacitor (6), including the HZO layered structure (3) of FIG. 3, and comprising a (doped) HZO layer (12) which is in direct contact with a metal oxide (MO) top layer (30). The layered structure (3) is placed between two metal layers which function as electrodes (13, 14). The MIM capacitor (6) is supported on a support (11).

FIG. 7 illustrates a cross-sectional view of a MIM capacitor (7), including the HZO layered structure (4) of FIG. 4, and comprising a metal oxide (MO) surface layer (20), which is in direct contact with a (doped) HZO layer (12), which again is in direct contact with a metal oxide (MO) top layer (30). The layered structure (4) is placed between two metal layers which function as electrodes (13, 14). The MIM capacitor (7) is supported on a support (11).

In some embodiments, the metal M in the MO layer is a metal from the p-block, d-black or f-block of the periodic table. In some embodiments, the metal M in the MO layer is a transition metal.

These metals may have two or more stable oxidation states, which would allow oxygen transfer to the HZO layer.

In some embodiments, the metal M in the MO layer may form at least two different metal oxides.

In some embodiments, the MO layer is provided with the metal M in at least the second lowest stable positive oxidation state. This means that there is at least one lower stable positive oxidation state for the metal to fall back to after oxygen transfer to the HZO layer has occurred. This may prevent the formation of metallic M (i.e., with an oxidation state of 0) in the MO layer.

In some embodiments, the metal (Mⁱ) in the MO surface layer and/or the MO top layer is at an highest initial oxidation state i, preferably at the moment of contact with the HZO layer, and wherein the direct contact with the doped HZO layer provides that oxygen is transferred from the MO surface layer and/or the MO top layer to the doped HZO layer, thereby lowering the oxidation state of the metal (M^{s}) to a subsequent oxidation state(s), wherein the highest initial oxidation state (i) of the metal in the metal oxide, and the subsequent oxidation state(s) of the metal are stable oxidation states of the metal; and, wherein i>s.

As used herein, the term “the metal (Mⁱ)” refers to the metal M in oxidation state (i), which is stable and higher than the subsequent oxidation state(s) in (M^{s}). The oxidation state (i) does not need to be the highest possible oxidation state for the metal, but only needs to be higher than the subsequent oxidation state(s) in (M^{s}). Hence, the term “the metal (M^{s})” refers to a metal in an oxidation state(s), which is lower than the initial oxidation state (i), but higher than zero.

The term “stable oxidation state of a metal” as used herein may refers to an oxidation state that is positive and that result in fully occupied valence orbitals and/or half full occupied valence orbitals.

In some embodiments, whereas hafnium and zirconium in the HZO layer have only one stable oxidation state, being +4; the metal M in the MO layer may have at least two stable oxidation states, wherein at least part of the metal in the MO layer is present in the highest of these at least two oxidation states. This may have the effect that, when there are imperfections in the HZO layer, like oxygen defects or oxygen vacancies, oxygen transfer may occur from the MO layer to the HZO layer, as at least some of the metal oxide in the MO layer can donate oxygen, thereby reducing some of the metal M from the highest of the at least two oxidation states to the lower of the two oxidation states, but yet forming a stable metal oxide in that lower oxidation state.

In some embodiments, the metal M in the MO surface layer and/or the MO top layer is selected from the group consisting of Sn, Ce, Cu, Co, Ge, V, Nb, Ta, Cr, Mo, W, Mn, Fe, Ru, Rh, Ir, Pd, Pt, In, and Pb. These metals may have at least two positive oxidation states. Table 1 provide an overview of stable oxidation states for some metals, disclosed herein.

TABLE 1
Metals M and their stable oxidation states

| | | | | | | | |
|---|---|---|---|---|---|---|---|
| Sn | +2, +4 | V | +2, +3, +4, +5 | W | +4, +6 | Ir | +1, +3, +4 |
| Ce | +3, +4 | Nb | +5 | Mn | +2, +3, +4, +6, +7 | Pd | +2, +4 |
| Cu | +1, +2 | Ta | +5 | Fe | +2, +3 | Pt | +2, +4 |
| Co | +2, +3 | Cr | +2, +3, +6 | Ru | +3, +4 | In | +3 |
| Ge | +2, +4 | Mo | +4, +6 | Rh | +3 | Pb | +2, +4 |

In some embodiments, the metal M in the MO surface layer and/or the MO top layer is selected from the group consisting of Sn, Ce, Cu, Co, and Ge.

In some embodiments, the highest initial oxidation state (i) is at least +2, preferably at least +3, preferably at least +4. In some embodiments, the difference between the highest initial oxidation state (i) and the subsequent oxidation state(s) is at least 1, preferably at least 2. In some embodiment, the subsequent oxidation state(s) of the metal is higher than 0, preferably at least +1.

In some embodiments, the metal oxide (MO) (i.e., of the MO surface layer and/or the MO top layer) is selected from the group consisting of SnO₂, wherein the highest initial oxidation state (i) of the Sn in the oxide is +4, CeO₂, wherein the highest initial oxidation state (i) of the Ce in the oxide is +4, CuO, wherein the highest initial oxidation state (i) of the Cu in the oxide is +2, Co₂O₃, wherein the highest initial oxidation state (i) of the Co in the oxide is +3, Co₃O₄, wherein the highest initial oxidation state (i) of the Co in the oxide is +3, GeO₂, wherein the highest initial oxidation state (i) of the Ge in the oxide is +4.

In some embodiments, the metal oxide (MO) is SnO₂, wherein the highest initial oxidation state (i) of the Sn in the oxide is +4, and which may be reduced, preferably by contact with an imperfect HZO layer, to SnO, wherein the subsequent oxidation state(s) is +2.

In some embodiments, the metal oxide (MO) is CeO₂, wherein the highest initial oxidation state (i) of the Ce in the oxide is +4, and which may be reduced, preferably by contact with an imperfect HZO layer, to Ce₂O₃, wherein the subsequent oxidation state(s) is +3.

In some embodiments, the metal oxide (MO) is CuO, wherein the highest initial oxidation state (i) of the Cu in the oxide is +2, and which may be reduced, preferably by contact with an imperfect HZO layer, to Cu₂O, wherein the subsequent oxidation state(s) is +1.

In some embodiments, the metal oxide (MO) is Co₂O₃, wherein the highest initial oxidation state (i) of the Co in the oxide is +3, and which may be reduced, preferably by contact with an imperfect HZO layer, to CoO, wherein the subsequent oxidation state(s) is +2.

In some embodiments, the metal oxide (MO) is Co₃O₄, wherein the oxidation state of Co is a mixture of +2 and +3, hence the highest initial oxidation state (i) of the Co in the oxide is +3, and which may be reduced, preferably by contact with an imperfect HZO layer, to CoO, wherein the subsequent oxidation state(s) is +2.

In some embodiments, the metal oxide (MO) is GeO₂, wherein the highest initial oxidation state (i) of the Ge in the oxide is +4, and which may be reduced, preferably by contact with an imperfect HZO layer, to GeO, wherein the subsequent oxidation state(s) is +2.

In various embodiments, the formation of a film comprising a hafnium oxide and/or a zirconium oxide, e.g., a HZO film, or layer on a substrate as described herein is performed by a cyclical deposition process, such as an atomic layer deposition process, or a cyclical chemical vapor deposition process. In some embodiments, the cyclical deposition process comprises one or more cycles. In some embodiments, the method as disclosed herein comprises at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles.

In some embodiments, a cycle comprises four or more pulses. In some embodiments, at least one pulse involves a self-limiting surface reaction. In some embodiments, all the pulses involve a self-limiting surface reaction. In some embodiments, a cycle comprises a hafnium precursor pulse, a zirconium precursor pulse, an oxygen reactant pulse, and a dopant precursor pulse. In some embodiments, the hafnium precursor pulse comprises, providing one or more hafnium precursor(s) into the reaction chamber. In some embodiments, the zirconium precursor pulse comprises, providing one or more zirconium precursor(s) into the reaction chamber. In some embodiments, the oxygen reactant pulse comprises, providing one or more oxygen reactant(s) into the reaction chamber. In some embodiments, the dopant precursor pulse comprises, providing one or more dopant precursor(s) into the reaction chamber. Hence in these embodiments, a thin layer can be formed, supported by at least a part of the substrate, wherein the thin layer comprises hafnium, zirconium, oxygen, and a dopant.

It shall be understood that any two steps and/or pulses can be separated by a purge. Thus, in some embodiments, the step of providing the one or more precursors, and the step of providing the oxygen reactant are separated by a purge (e.g., an intra-cycle purge). In some embodiments, subsequent cycles are separated by a purge.

In some embodiments, the method as disclosed herein provides that the one or more cycles, comprising the steps of contacting one or more precursor with at least a part of the substrate into the reaction chamber, is quasi free from oxygen, and preferably fully oxygen free.

In some embodiments, a metal oxide (MO) surface layer may be provided, or formed on the substrate. In some embodiments, a metal oxide (MO) top layer may be provided or formed on the HZO layer. In one aspect, the HZO layer comprises a doped HZO layer.

In some embodiments, the metal oxide surface layer and the metal oxide top layer are deposited on the substrate, and the HZO layer, respectively. In various, the deposition of the metal oxide surface layer and the metal oxide top layer may be carried out in the reaction chamber, preferably by one or more metal precursor pulses and one or more oxygen reactant pulses. In such examples at least a part of the substrate and/or the HZO layer is contacted with one or more metal precursors and one or more oxygen reactants by introducing the metal precursor(s) and the oxygen reactants(s) into the reaction chamber. In numerous examples, the reaction chamber is purged between the forming of the metal oxide layers (e.g., a metal oxide surface layer and/or a metal oxide top layer) and the forming of the HZO layer.

In some embodiments, the substrate comprises a semiconductor material, including, but not limited to, silicon, germanium, silicon germanium, gallium arsenide, gallium nitride, and silicon carbide. In certain embodiments, the substrate is a silicon substrate (e.g., a single crystalline silicon (Si) substrate. In such embodiments, the silicon substrate can comprise one or more dielectric layers, such as, silicon oxide, for example.

In some embodiments, the substrate comprises a continuous substrate that may extend beyond the bounds of a process/reaction chamber where the deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

In various embodiments, the methods as disclosed herein provide that the HZO layer or the layered HZO structures are formed without any intervening vacuum break. Intervening vacuum breaks can introduce process pauses, which are not desirable in high-throughput manufacturing scenarios, thus leading to a more continuous and streamlined process. Also, deposition techniques, such as ALD thrive on continuous and controlled precursor exposure. Interrupting the process with vacuum breaks may introduce variations in film growth and quality, and may also increase the contamination risk since intervening vacuum breaks can potentially introduce contaminants or oxygen, particularly if the vacuum chamber is not thoroughly purged during the break. Therefore, continuous deposition without introducing intervening vacuum breaks reduces the risk of introducing impurities in the HZO layer.

In various embodiments, the methods as disclosed herein provide that one or more cycles of the cyclical deposition processes comprise a step of providing an oxygen reactant into the reaction chamber (along with a metal precursor and an optional dopant precursors), thereby forming a metal, oxygen, and optionally a dopant, containing layer on at least part of the substrate. In other words, the present disclosure alternatively or additionally provides the intentional introduction of an oxygen reactant during one or more of the cycles. The skilled person understands that different orders of pulses may be possible. Advantageously, by controlling the amount of oxygen and/or oxygen contaminants during each deposition cycle, the present disclosure may lower the amount of surface defects during deposition of the layers and may control the equivalent oxide thickness (EOT), as well forming well defined layers of a desired thickness without lowering conductivity and/or capacitance. Moreover, the HZO layer structures formed by the embodiments provided may provide additional flexibility since the reactive oxide-containing layers may be used for subsequent reactions or deposits of material.

In particular embodiments, suitable oxygen reactants are selected from at least one of H₂O, D₂O, H₂O₂, O₃, O₂, N₂O, NO, N₂O₅, SO₂, oxygen-containing plasma, and oxygen radicals.

As used herein, the term “deposition” or “cyclic deposition” or “cyclic deposition process” or “cyclical deposition process” refers to a sequential introduction of metal precursors (and/or reactants) into a reaction chamber to deposit a layer or film over a substrate and includes processing techniques such as atomic layer deposition (ALD), cyclical chemical vapor deposition (cyclical CVD), and hybrid cyclical deposition processes that include an ALD component and a cyclical CVD component.

In various embodiments, a deposition process as disclosed herein can refer to an atomic layer deposition process. In such embodiments, one deposition cycle may form a film or layer having an average layer thickness of about 0.10 nm. However, the experimental thickness may vary depending on the amount and type of cycles, and available reaction sites on the substrate. In certain embodiments, the methods as disclosed herein deposit layers having an average thickness of 1 nm or less, or 0.75 nm or less, preferably 0.50 nm or less, or 0.4 nm or less, or 0.3 nm or less, preferably 0.25 nm or less, or 0.2 nm or less, more preferably 0.10 nm or less. In some embodiments, the layers are deposited at a rate of 0.10 nm, or less per cycle (e.g., by alternating pulses of precursor(s)/reactive gas(es), and purge gases). A layer of lower thickness may be desirable for many electronics applications, including work function and/or threshold voltage adjustment in transistors.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a (metal) precursor is introduced into a reaction chamber and is chemisorbed on a deposition surface (e.g., a substrate surface that can include a previously deposited material from a previous ALD cycle or other material) and forms an chemisorbed layer, e.g. about a monolayer or sub-monolayer, that does not readily react with additional precursor (i.e., a self-limiting reaction). Thereafter, in some cases, a reactant (e.g., another precursor or reaction gas) may subsequently be introduced into the reaction chamber to react with the chemisorbed layer to form the desired material layer on the deposition surface. Purging steps can be utilized during one or more repetitions, e.g., during each deposition step, to remove any excess precursor from the process chamber and/or remove any excess reactant and/or reaction byproducts from the reaction chamber. Note that, as used herein, ALD processes are not necessarily comprised of a sequence of self-limiting surface reactions. Advantageously, the method of the present disclosure allows the formation of HZO layered structures that do not require full film closure to work, thereby allowing faster deposition processes having a larger error-tolerance compared to previous formation processes.

Typically, a cycle comprises three or more pulses. In some embodiments, at least one pulse involves a self-limiting surface reaction. In some embodiments, all pulses involve a self-limiting surface reaction. In some embodiments, an oxygen reactant pulse is carried out after each hafnium precursor pulse and/or after each zirconium precursor pulse. Using an oxygen reactant pulse after a precursor pulse can allow the formation of thin layers on the provided substrate. After a precursor pulse is introduced into the reaction chamber, any excess or unreacted precursor (along with any reaction byproducts) can be removed from the reaction chamber before introducing a subsequent precursor/reactant. By doing so, unwanted accumulation of precursor molecules can be prevented, which could otherwise lead to undesired layers properties or non-uniformity of the layer. Since the precursor pulse also involves chemisorption, where precursor molecules will absorb onto the substrate's surface and react with it, providing an oxygen reactant pulse will help to complete the surface reactions and promote the formation of the desired film on the substrate, assists in removing any residual absorbed precursor molecules and reduces the existence of impurities and defects in the formed film.

In some embodiments, the dopant precursor pulse is carried out after the hafnium precursor pulse, without any intervening oxygen reactant pulse. In the hafnium precursor pulse, the hafnium precursor is provided into the reaction chamber. In the dopant precursor pulse, the dopant compound is provided into the reaction chamber. Hence, a thin layer is formed on at least a part of the substrate containing hafnium and dopant. In some embodiments, the dopant precursor pulse is carried out after the zirconium precursor pulse, without any intervening oxygen reactant pulse. In the zirconium precursor pulse, the zirconium precursor is provided into the reaction chamber. In the dopant precursor pulse, the dopant compound is provided into the reaction chamber. Hence, a thin layer is formed on at least a part of the substrate containing at least zirconium and a dopant.

It shall be understood that any two steps and/or pulses can be separated by a purge. Thus, in some embodiments, the step of contacting the one or more precursors and/or the step of contacting the dopant compound are separated by a purge. In some embodiments, subsequent cycles are separated by a purge.

In particular embodiments, the method as disclosed herein provides that the one or more cycles, comprising the steps of contacting one or more precursor with at least a part of the substrate and providing the nitrogen compound or another noble gas into the reaction chamber, is quasi free from oxygen, and preferably fully oxygen free. More specifically, the disclosed method provides that the deposition of the HZO layer is free from oxygen contaminants, thus lowering the equivalent oxide thickness (EOT) of the dipole and the amount of deposition defects.

In some embodiments, the hafnium precursor pulse, the zirconium precursor pulse, the oxygen reactant pulse, and/or the dopant precursor pulse comprises a plurality of micropulses. Micropulsing is a technique used to maintain fine control over thin-film growth, composition, and the envisaged properties. Micropulsing can involve delivering short bursts of precursor, or reactant gases, with precise timing and allows for a better utilization of the precursor material. By delivering small, controlled amounts of precursor, the methods provided can be optimized such that most of the precursor molecules are chemically absorbed and are able to react with the substrate. It is particularly valuable in processes that require precise atomic or molecular layer deposition and where avoiding excessive precursor exposure can be critical for achieving desired film characteristics, as is the case for MIM CAPS having a peak of K at a voltage region of interest.

Non-limiting examples of dopant elements may include aluminum, silicon, nickel, germanium, gallium, and carbon.

In particular embodiments, the method as disclosed herein provides for a variation in concentration of the dopant element in the HZO layer. The concentration of the dopant element ranges between 0.50 and 8.0% of the relative dopant element concentration, more particularly between 1.0 and 5.0% of the relative dopant element concentration, and even more particularly between 2.0 and 4.50% of the relative dopant element concentration.

Alternatively, the molar atomic concentration of the dopant element ranges between 0.50 at. % and 15.0 at. %, more in particular between 0.50 at. % and 10.0 at. %, more in particular between 1.0 at. % and 5.0 at. %, and more in particular between 2.00 at. % and 4.50 at. %. Preferably, the dopant element comprises a molar atomic percentage of less than 10.0 at. %, such as less than 9.0 at. %, or less than 8.0 at. %, or less than 7.0 at. %, or less than 6.0 at. %, or less than 5.0 at. %, or less than 4.0 at. %, or less than 3.0 at. %, or less than 2.0 at. %, or less than 1.0 at. %, or less than 0.5 at. %.

In particular embodiments, the dopant element is Al. Further, the dopant precursor is a low-reactivity precursor, preferably a low-reactivity aluminum precursor represented by the general formula Al(R¹)³, wherein each R¹ is independently selected from the group consisting of hydrogen, halogen, alkyl, alkenyl, N(R²)², cycloalkyl, and alkoxy; and wherein each R² is chosen from hydrogen, alkyl, or alkenyl. In some embodiments, each R¹ is independently selected from the group consisting of hydrogen, halogen, C₁₋₈alkyl, C₂₋₈alkenyl, C₃₋₈cycloalkyl, and C₁₋₈alkoxy; and each R² is chosen from hydrogen, C₁₋₈alkyl, or C₂₋₈alkenyl. In some embodiments, each R¹ is independently selected from the group consisting of hydrogen, halogen, C₁₋₄alkyl, C₂₋₄alkenyl, C₃₋₈cycloalkyl, and C₁₋₄alkoxy; and each R² is chosen from hydrogen, C₁₋₄alkyl, or C₂₋₄alkenyl. In some embodiments, the aluminum precursor is selected from the group consisting of aluminum hydride (AlH₃), aluminum trifluoride (AlF₃), aluminum trichloride (AlCl₃), aluminum tribromide (AlBr₃), aluminum triiodide (AlI₃), triethylaluminium (Al(CH₃)₃), triethylaluminium (Al(C₂H₅)₃, tri(isopropyl)aluminum (Al(ⁱPr)₃), tetra-n-butylaluminum (Al(C₄H₉)₃), tetra-t-butyl aluminum (Al(O^{t}Bu)₃), aluminum methoxide (Al(OCH₃)₃), aluminum ethoxide (Al(OC₂H₅)₃), aluminum isopropoxide (Al(OⁱPr)₃), aluminum n-butoxide (Al(OC₄H₉)₃), and aluminum t-butoxide (Al(O^{t}Bu)₃).

In some embodiments, the dopant element is Si. Further, the dopant precursor is a low-reactivity precursor, the dopant precursor preferably being a low-reactivity silicon precursor selected from the group consisting of silicon tetraacetate (Si(OOCCH₃)₄), and Si(R³)₄, wherein each R³ is independently selected from the group consisting of hydrogen, halogen, alkyl, alkenyl, N(R⁴)₂, cycloalkyl, and alkoxy; and wherein each R⁴ is chosen from hydrogen, alkyl, or alkenyl.

In some embodiments, each R³ is independently selected from the group consisting of hydrogen, halogen, C₁₋₈alkyl, C₂₋₈alkenyl, C₃₋₈cycloalkyl, and C₁₋₈alkoxy; and each R⁴ is chosen from hydrogen, C₁₋₈alkyl, or C₂₋₈alkenyl. In some embodiments, each R³ is independently selected from the group consisting of hydrogen, halogen, C₁₋₄alkyl, C₂₋₄alkenyl, C₃₋₈cycloalkyl, and C₁₋₄alkoxy; and each R⁴ is chosen from hydrogen, C₁₋₄alkyl, or C₂₋₄alkenyl. In certain embodiments, the silicon precursor is selected from the group consisting of silane (SiH₄), silicon tetrafluoride (SiF₄), silicon tetrachloride (SiCl₄), silicon tetrabromide (SiBr₄), silicon tetraiodide (SiI₄), tetramethylsilane (Si(CH₃)₄), tetraethylsilane (Si(C₂H₅)₄, tetra(isopropyl)silane (Si(ⁱPr)₄), tetra-n-butylsilane (Si(C₄H₉)₄), tetra-t-butylysilane (Si(O^{t}Bu)₄), tetramethoxysilane (Si(OCH₃)₄), tetraethoxysilane (Si(OC₂H₅)₄), tetra(isopropoxy)silane (Si(OⁱPr)₄), tetra-n-butoxysilane (Si(OC₄H₉)₄), tetra-t-butoxysilane (Si(O^{t}Bu)₄), and tris(dimethylamino)silane (Si(N[CH₃]₂)₃).

In some embodiments, the dopant element is Ge. Further, the dopant precursor is a low-reactivity precursor, preferably a low-reactivity germanium precursor represented by the general formula Ge(R⁵)₄, wherein each R⁵ is independently selected from the group consisting of hydrogen, halogen, alkyl, alkenyl, N(R⁶)₂, cycloalkyl, and alkoxy; and wherein each R⁶ is chosen from hydrogen, alkyl, or alkenyl. In some embodiments, each R⁵ is independently selected from the group consisting of hydrogen, halogen, C₁₋₈alkyl, C₂₋₈alkenyl, C₃₋₈cycloalkyl, and C₁₋₈alkoxy; and each R⁶ is chosen from hydrogen, C₁₋₈alkyl, or C₂₋₈alkenyl. In some embodiments, each R⁵ is independently selected from the group consisting of hydrogen, halogen, C₁₋₄alkyl, C₂₋₄alkenyl, C₃₋₈cycloalkyl, and C₁₋₄alkoxy; and each R⁶ is chosen from hydrogen, C₁₋₄alkyl, or C₂₋₄alkenyl. In some embodiments, the germanium precursor is selected from the group consisting of germane (GeH₄), germanium tetrafluoride (GeF₄), germanium tetrachloride (GeCl₄), germanium tetrabromide (GeBr₄), germanium tetraiodide (GeI₄), tetramethylgermanium (Ge(CH₃)₄), tetraethylgermanium (Ge(C₂H₅)₄, tetra(isopropyl)germanium (Ge(ⁱPr)₄), tetra-n-butylgermanium (Ge(C₄H₉)₄), tetra-t-butylgermanium (Ge(O^{t}Bu)₄), tetramethoxygermanium (Ge(OCH₃)₄), tetraethoxygermanium (Ge(OC₂H₅)₄), tetra(isopropoxy)germanium (Ge(OC₃H₇)₄), tetra-n-butoxygermanium (Ge(OC₄H₉)₄), tetra-t-butoxygermanium (Ge(O^{t}Bu)₄), and tris(dimethylamino)germanium (Ge(N[CH₃]₂)₃). In some embodiments, HZO layers doped with Ge, Si and/or Al can be particularly advantageous in forming HZO layers that adopt to a primarily tetragonal phase composition, thus shifting the maximum κ peaks to a voltage region of interest, while promoting a better linearity.

A low-reactivity precursor is a chemical compound that has limited reactivity under specific conditions. In thin-film deposition techniques, such as ALD, a low-reactivity precursor is a precursor compound that does not readily undergo chemical reactions or decomposition at low temperatures or under the conditions of the deposition process. In the described methods, the goal can be to deposit thin layers in a controlled and uniform manner. Using a low-reactivity precursor may be desirable because such precursors may allow for precise control of the film growth without premature reactions or decomposition on the substrate surface. Additionally, low-reactivity precursors can be useful when the deposition process needs to occur at a temperature which is compatible with the substrate and the desired film properties. Since the reactivity of low-reactivity precursors can be adjusted by varying the process conditions such as temperature, pressure and exposure time, small variations may alter the reactivity of the low-reactivity precursor and thus accommodate for a specific deposition process, material, and desired film characteristics.

In particular embodiments, the method as disclosed herein provides that the hafnium precursor is represented by the following general formula (I),

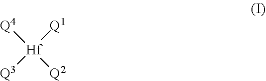

wherein Q¹, Q², Q³, Q⁴ are each independently chosen from the group consisting of halogen, alkyl, alkenyl, N(R⁷)₂, alkoxy, heteroalkyl, cycloalkyl, aryl, and cyclopentadienyl; and wherein each R⁷ is independently hydrogen, alkyl, or alkenyl.

In some embodiments, the present disclosure provides that Q¹, Q², Q³, Q⁴ are each independently chosen from the group consisting of halogen, C₁₋₈alkyl, C₂₋₈alkenyl, N(R⁷)₂, C₁₋₈alkoxy, heteroC₁₋₈alkyl, C₃₋₈cycloalkyl, C₆₋₁₀aryl, and cyclopentadienyl; wherein each R⁷ is independently hydrogen, C₁₋₈alkyl, or C₂₋₈alkenyl. In some embodiments, the present disclosure provides that Q¹, Q², Q³, Q⁴ are each independently chosen from the group consisting of halogen, C₁₋₄alkyl, C₂₋₄alkenyl, N(R⁷)₂, C₁₋₄alkoxy, heteroC₁₋₄alkyl, C₃₋₈cycloalkyl, C₆₋₁₀aryl, and cyclopentadienyl; wherein each R⁷ is independently hydrogen, C₁₋₄alkyl, or C₂₋₄alkenyl. In some embodiments, the method as disclosed herein provides that the hafnium precursor is chosen from the group consisting of HfCl₄, HfBr₄, Hfl₄, HfMe₄, HfEt₄, Hf(nPr)4, Hf(iPr)₄, Hf(nBu)₄, Hf(tBu)₄, Hf(NMe₂)₄, Hf(NEt₂)₄, Hf[MeEtN]₄, HfCp[(NMe₂)₃], Hf(OMe)₄, Hf(OEt)₄, Hf(OnPr)₄, Hf(OiPr)₄, Hf(OnBu)₄, Hf(OtBu)₄, Hf[(CpMe)₂][OMe][Me], Hf[(CpMe)₂][(Me)₂], Tetrakis(1-methoxy-2-methyl-2-propoxy)hafnium (Hf(mmp)₄).

Using a hafnium precursor when depositing thin layers on a substrate commonly results in hafnium-based materials having a high dielectric constant (κ) compared to traditional silicon dioxide (SiO₂), enabling better control of gate leakage and improved device performance.

In particular embodiments, the method as disclosed herein provides that the zirconium precursor is represented by the following general formula (II),

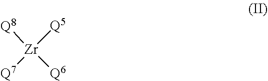

wherein Q⁵, Q⁶, Q⁷, Q⁸ are each independently chosen from the group consisting of halogen, alkyl, alkenyl, N(R⁸)₂, alkoxy, heteroalkyl, cycloalkyl, aryl, and cyclopentadienyl; wherein each R⁸ is independently hydrogen, alkyl, or alkenyl.

In some embodiments, the present disclosure provides that Q⁵, Q⁶, Q⁷, Q⁸ are each independently chosen from the group consisting of halogen, C₁₋₈alkyl, C₂₋₈alkenyl, N(R⁸)₂, C₁₋₈alkoxy, heteroC₁₋₈alkyl, C₃₋₈cycloalkyl, C₆₋₁₀aryl, and cyclopentadienyl; wherein each R⁸ is independently hydrogen, C₁₋₈alkyl, or C₂₋₈alkenyl. In some embodiments, the present disclosure provides that Q⁵, Q⁶, Q⁷, Q⁸ are each independently chosen from the group consisting of halogen, C₁₋₄alkyl, C₂₋₄alkenyl, N(R⁸)₂, C₁₋₄alkoxy, heteroC₁₋₄alkyl, C₃₋₈cycloalkyl, C₆₋₁₀aryl, and cyclopentadienyl; wherein each T⁸ is independently hydrogen, C₁₋₄alkyl, or C₂₋₄alkenyl. In some embodiments, the method as disclosed herein provides that the zirconium precursor is chosen from the group consisting of ZrCl₄, ZrBr₄, Zrl₄, ZrMe₄, ZrEt₄, Zr(nPr)₄, Zr(iPr)₄, Zr(nBu)₄, Zr(tBu)₄, Zr(NMe₂)₄, Zr(NEt₂)₄, Zr[MeEtN]₄, ZrCp[(NMe₂)₃], Zr(OMe)₄, Zr(OEt)₄, Zr(OnPr)₄, Zr(OiPr)₄, Zr(OnBu)₄, Zr(OtBu)₄, Zr[(CpMe)₂][OMe][Me], Zr[(CpMe)₂][(Me)₂], Tetrakis(1-methoxy-2-methyl-2-propoxy)zirconium (Zr(mmp)₄).

Using a zirconium precursor when depositing thin films on a substrate commonly results in zirconium-based materials having a high dielectric constant κ compared to traditional silicon dioxide (SiO₂), which helps to maintain gate capacitance while reducing gate oxide thickness in scaled-down applications. Further, using a zirconium precursor creates a barrier coating in microelectronics to prevent diffusion of metals into the dielectric layer, thus enhancing the reliability and performance of interconnect structures.

In particular embodiments, the method as disclosed herein provides that the decomposition temperature of the dopant precursor is higher compared to the operating temperature to form the doped hafnium zirconium oxide (HZO) layer. The decomposition temperature refers to the temperature at which the precursor molecule breaks down or undergoes chemical reactions that lead to the deposition of the dopant material on the substrate surface. The decomposition temperature of a dopant precursor can be an important parameter when using it in thin-film deposition processes like ALD. If the precursor decomposes at a temperature significantly lower than the process temperature, premature decomposition might occur in the gas phase, leading to the deposition of unintended reaction by-products and poor film quality. Further, precursor decomposition at the proper temperature ensures that the dopant material is deposited in its desired form without incorporating impurities or producing defective films. However, if the precursor decomposes at too high a temperature, it might not fully decompose on the substrate surface, leading to incomplete film growth and wasted precursor.

Therefore, in particular embodiments, the method as disclosed herein provides that the operating temperature to form the doped HZO layer is between 150° C. and 450° C., preferably between 250° C. and 350° C., more preferably around 300° C.

Typically, one deposition cycle may form a film or layer of about 0.10 nm. However, the experimental thickness may vary depending on the amount and type of cycles and available reaction sites on the substrate. In some embodiments, the method as disclosed herein provides that the HZO layer has an average thickness of 1 nm or less, or 0.75 nm or less, preferably 0.50 nm or less, or 0.4 nm or less, or 0.3 nm or less, preferably 0.25 nm or less, or 0.2 nm or less, more preferably 0.10 nm or less. In some embodiments, the HZO layer is grown at a rate of 0.10 nm or less per alternating pulses of precursor(s)/reactive gas(es), and purge (e.g., inert carrier) gas(es).

In order to create a doped HZO layer on a substrate, a first pulse with a hafnium precursor, a second pulse with a zirconium precursor, and a third pulse with an oxygen reactant, are introduced into the reaction chamber such that at least part of the substrate is contacted with the hafnium precursor, the zirconium precursor, the oxygen reactant, and/or the dopant precursor to form a desired thin layer. A precursor pulse typically lasts from at least 0.01 s to at most 120 s, while an oxygen reactant pulse lasts from at least 0.1 s to at most 20 s. One precursor will typically react with the substrate's surface, while the other precursors remain inert during that reaction. During the repeated deposition cycles, the precursors can be introduced one at a time, allowing them to react with the surface in a self-limiting manner. When the first precursor is introduced, it reacts with the substrate's surface, forming a chemisorbed layer. Typically, excess precursor is purged or removed from the reaction chamber before the next precursor is introduced, which will then react with the already formed chemisorbed layer from the previous step, thus forming a new layer. Once all available reactive sites on the substrate's surface are saturated, the reaction will stop and a thin film which has grown atom-by-atom is created, ensuring precise control over the film thickness.

In some embodiments, the hafnium, zirconium and/or dopant precursor pulse(s) lasts from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the oxygen reactant pulse lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

The zirconium or the hafnium element in the respective precursor may be in any suitable oxidation state, e.g., in oxidation state +1, in oxidation state +2, in oxidation state +3,in oxidation state +4. The precursor(s) may have a low carbon impurity content e.g., a carbon content of 1.0, or 0.1 atomic percent, or less. The one or more precursor(s) may comprise a ligand. The ligand is typically an ion or molecule with a functional group capable of binding to the central metal atom to form a coordination complex. In some embodiments, the method as disclosed herein provides that the ligand is chosen from the group including at least one of amine, alkenyl, carbonyl, alkoxide, beta-diketone, diazadiene, amidinate, halogen, guanidinate, triazenide, carboxylate, cyclopentadienyl, and/or aryl.

In some embodiments, the dopant precursor comprise a dopant element is selected from the group consisting of Mn, Bi, Sr, B, N, Li, V, S, Sc, P, N, Ni, Ga, Mg, Cr, Sn, Sb, La, Y, Mo and Al.

It shall be understood that the following embodiments can apply to any one of the methods disclosed herein, irrespective of the precursor and/or reactant that is used in such methods, unless a corresponding embodiment would render the method in question unworkable.

In some embodiments, the HZO layer and/or MO layer is deposited at a temperature of at least 100° C. to at most 500° C., or at a temperature of at least 200° C. to at most 450° C., or at a temperature of at least 300° C. to at most 400° C., or at a temperature of at least 350° C. to at most 450° C.

In some embodiments, the precursor(s) is provided to the reaction chamber from a precursor source maintained at a temperature of at least 25° C. to at most 200° C., or at a temperature of at least 50° C. to at most 150° C., or at a temperature of at least 75° C. to at most 125° C.

In some embodiments, the oxygen reactant is provided to the reaction chamber from an oxygen source maintained at a temperature of at least 25° C. to at most 200° C., or at a temperature of at least 50° C. to at most 150° C., or at a temperature of at least 75° C. to at most 125° C.

In some embodiments, the HZO layer and/or MO layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

The HZO layer and/or MO layer can be deposited in any suitable reactor. Thus, in some embodiments, the HZO layer and/or MO layer is deposited in a cross-flow reactor. In some embodiments, the HZO layer and/or MO layer is deposited in a showerhead reactor. In some embodiments, the HZO layer and/or MO layer is deposited in a hot-wall reactor. In some embodiments, the HZO layer and/or MO layer is deposited in a cold-wall reactor. Doing so can advantageously enhance uniformity and/or repeatability of the HZO layer and/or MO layer deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the metal precursor is provided to the reaction chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature-controlled precursor vessel is maintained at a temperature of at least −50° C. to at most 20° C., or at a temperature of at least 20° C. to at most 250° C., or at a temperature of at least 100° C. to at most 200° C.

In some embodiments, the precursor(s) is provided to the reaction chamber by means of a carrier gas. Exemplary carrier gasses include nitrogen (N₂) and a noble gas such as He, Ne, Ar, Xe, or Kr.

In particular embodiments, the formed HZO layer has a dielectric constant larger than the dielectric constant of silicon oxide (e.g., SiO₂) such as higher than about 7. In some embodiments, besides hafnium oxide (HfO₂) and zirconium oxide (ZrO₂), the HZO layer may further comprises tantalum oxide (Ta₂O₅), titanium oxide (TiO₂), hafnium silicate (HfSiOₓ), aluminum oxide (Al₂O₃) or lanthanum oxide (La₂O₃), mixtures thereof, or laminates thereof. The method as disclosed herein may further comprise the step of forming a conductive layer on the high-κ dielectric. The further conductive layer may comprise a metal, or a metal nitride, for examples, such as, aluminum, copper, or cobalt, and the like.

In some embodiments, the semiconductor structure may comprise the following sequence of layers, in the order given: a SiO₂, a MO surface layer, a HZO layer, and a conductive layer.

In some embodiments, the semiconductor structure may comprise the following sequence of layers, in the order given: a SiO₂, a HZO layer, a MO top layer and optionally a conductive layer.

In some embodiments, the semiconductor structure may comprise the following sequence of layers, in the order given: a SiO₂, a MO surface layer, a HZO layer, a MO top layer and optionally a conductive layer.

In some embodiments, the (doped) HZO layer is characterized by having a thickness of at least 2.0 nm, preferably at least 5.0 nm, preferably at least 10.0 nm, preferably at least 15.0 nm. In some embodiments, the (doped) HZO layer is characterized by having a thickness of at least 2.0 nm to at most 30.0 nm, preferably at least 5.0 nm to at most 25.0 nm, preferably at least 10.0 nm to at most 20.0 nm.

In some embodiments, the MO layer top layer and/or MO surface layer is characterized by having a thickness of at least 2.0 nm to at most 20.0 nm, preferably at least 5.0 nm to at most 15.0 nm, preferably at least 10.0 nm to at most 15.0 nm.

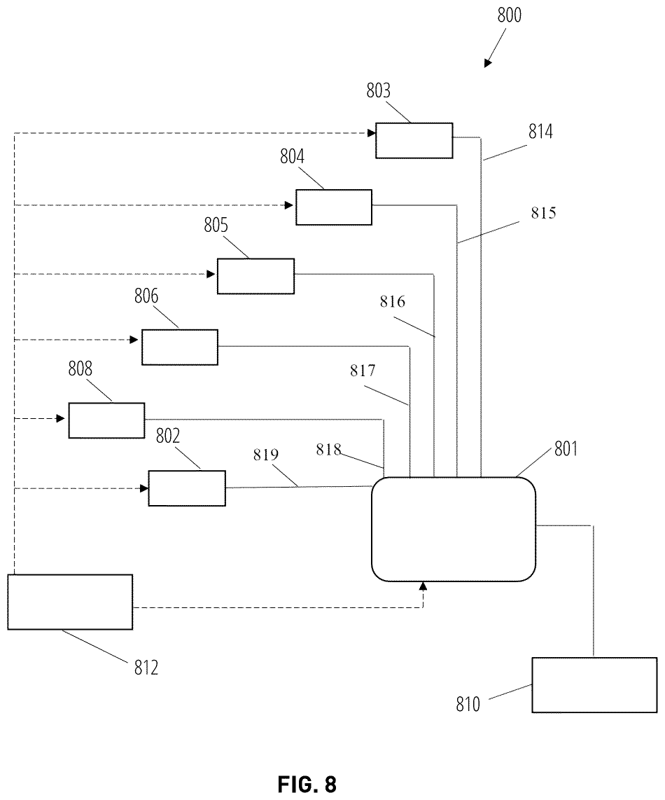

Various embodiments of the present disclosure also provide systems, wherein such systems are configured to perform the methods as disclosed herein. FIG. 8 illustrates such a system (800) in accordance with exemplary embodiments of the disclosure. In the illustrated example of FIG. 8, the system (800) can be used to perform a method as described herein and/or form a structure or device portion as described herein.

In the illustrated example, the system (800) includes one or more reaction chambers (801), a metal oxide precursor (802), a hafnium precursor source (803), a zirconium precursor source (804), an oxygen reactant source (805), a dopant precursor source (806), a purge gas source (808), an exhaust (810), and a controller (812). The reaction chamber (801) can include any suitable reaction chamber, such as an ALD reaction chamber.

The precursor sources (802)-(804) can include a vessel and one or more precursors as described herein-alone or mixed with one or more carrier (e.g., inert) gases. The dopant precursor source (806) can include a vessel, and one or more dopant compounds as described herein-alone or mixed with one or more carrier gases. The purge gas source (808) can include one or more inert gases such as N₂ or a noble gas, as described herein. The system (800) can include any suitable number of sources. The sources (802)-(808) can be coupled to reaction chamber (801) via lines (814)-(819), which can each include flow controllers, valves, heaters, and the like. The exhaust (810) can include one or more vacuum pumps.

The controller (812) includes electronic circuitry and software to selectively operate valves, manifolds, heaters, pumps, and other components included in the system (800). Such circuitry and components operate to introduce precursors, reactants, and purge gases from the respective sources (802)-(808). The controller (812) can control timing of gas pulse sequences, temperature of the substrate and/or reaction chamber, pressure within the reaction chamber, and various other operations to provide proper operation of the system (800). The controller (812) can include control software to electrically or pneumatically control valves to control flow of precursors, reactants (i.e., nitrogen compounds and/or oxygen compounds) and purge gases into and out of the reaction chamber (801). The controller (812) can include modules such as a software or hardware component, e.g., a FPGA or ASIC, which performs certain tasks. A module can advantageously be configured to reside on the addressable storage medium of the control system and be configured to execute one or more processes.

Other configurations of the system (800) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding precursors, reactants, and/or gases into the reaction chamber (801). Further, as a schematic representation of a system, many components have been omitted for simplicity of illustration, and such components may include, for example, various valves, manifolds, purifiers, heaters, containers, vents, and/or bypasses.

During operation of the reactor system (800), substrates, such as semiconductor wafers (not illustrated), are transferred from, e.g., a substrate handling system to reaction chamber (801). Once substrate(s) are transferred to the reaction chamber (801), one or more gases from the gas sources (802)-(808), such as precursors, reactants, carrier gases, and/or purge gases, are introduced into reaction chamber (801).

As an exemplary embodiment, the methods as disclosed herein can be performed using a system according to FIG. 8 as described herein. According to such embodiments, the precursor pulse comprises hafnium and zirconium and the dopant precursor pulse comprises Si, Al, or Ge.

Various embodiments of the present disclosure provide a layered doped HZO structure, obtained by the methods disclosed herein. Such doped hafnium zirconium oxide (HZO) layers can be employed as an insulator in a metal-insulator-metal capacitor (MIM CAPS).

The subject matter of the present disclosure includes all novel and nonobvious combinations and sub-combinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

What is claimed:

1. Method for forming a semiconductor structure, comprising the steps of:
a) providing a substrate into a reaction chamber;
b) executing one or more cycles, a cycle comprising:
i. a hafnium precursor pulse, wherein at least a part of the substrate is contacted with one or more hafnium precursors by introducing the one or more hafnium precursors into the reaction chamber;
ii. a zirconium precursor pulse, wherein at least a part of the substrate is contacted with one or more zirconium precursors by introducing the one or more zirconium precursors in the reaction chamber;
iii. an oxygen reactant pulse, wherein at least a part of the substrate is contacted with one or more oxygen reactants by introducing the one or more oxygen reactants in the reaction chamber; and
iv. a dopant precursor pulse, wherein at least a part of the substrate is contacted with one or more dopant precursors by introducing the one or more dopant precursors in the reaction chamber, thereby forming a doped hafnium zirconium oxide layer,
wherein the substrate comprises a metal oxide surface layer, and/or wherein the method further comprises the step of forming a metal oxide top layer on the doped hafnium zirconium oxide layer, thereby forming a layered doped hafnium zirconium oxide structure, the metal oxide surface layer and/or the metal oxide top layer being in direct contact with the doped hafnium zirconium oxide layer.

2. The method according to claim 1, wherein a metal (Mⁱ) in the metal oxide surface layer and/or the metal oxide top layer is at a highest initial oxidation state (i), and wherein the direct contact with the doped hafnium zirconium oxide layer provides that oxygen is transferred from the metal oxide surface layer and/or the metal oxide top layer to the doped hafnium zirconium oxide layer, thereby lowering the oxidation state of the metal (M^{s}) to a subsequent oxidation state(s), wherein the highest initial oxidation state (i) of the metal in the metal oxide surface layer and/or the metal oxide top layer, and the subsequent oxidation state(s) of the metal are stable oxidation states of the metal, and (i)>(s).

3. The method according to claim 1, wherein the doped hafnium zirconium oxide layer is formed at a temperature of at least 300° C. to at most 400° C.

4. The method according to claim 1, wherein the pressure in the reaction chamber is between about 0.1 Torr and about 100 Torr.

5. The method according to claim 1, wherein the oxygen reactant pulse is carried out after each hafnium precursor pulse and/or after each zirconium precursor pulse.

6. The method according to claim 5, wherein the dopant precursor pulse is carried out after the hafnium precursor pulse without any intervening oxygen reactant pulse.

7. The method according to claim 5, wherein the dopant precursor pulse is carried out after the zirconium precursor pulse without any intervening oxygen reactant pulse.

8. The method according to claim 1, wherein the hafnium precursor pulse, the zirconium precursor pulse, the oxygen reactant pulse, and/or the dopant precursor pulse comprises a plurality of micropulses.

9. The method according to claim 1, further comprises a post-annealing step.

10. The method according to claim 1, wherein the metal M in the metal oxide surface layer and/or the metal oxide top layer is selected from the group consisting of Sn, Ce, Cu, Co, Ge, V, Nb, Ta, Cr, Mo, W, Mn, Fe, Ru, Rh, Ir, Pd, Pt, In, and Pb.

11. The method according to claim 1, wherein the metal M in the metal oxide surface layer and/or the metal oxide top layer is selected from the group consisting of Sn, Ce, Cu, Co, and Ge.

12. The method according to claim 2, wherein the highest initial oxidation state (i) is at least +2.

13. The method according to claim 2, wherein the difference between the highest initial oxidation state (i) and the subsequent oxidation state(s) is at least 1.

14. The method according to claim 2, wherein the subsequent oxidation state(s) of the metal is higher than 0.

15. The method according to claim 2, wherein the metal oxide surface layer and/or the metal oxide top layer is selected from the group consisting of: SnO₂, wherein the highest initial oxidation state (i) of the Sn in the oxide is +4, CeO₂, wherein the highest initial oxidation state (i) of the Ce in the oxide is +4, CuO, wherein the highest initial oxidation state (i) of the Cu in the oxide is +2, Co₂O₃, wherein the highest initial oxidation state (i) of the Co in the oxide is +3, Co₃O₄, wherein the highest initial oxidation state (i) of the Co in the oxide is +3, GeO₂, wherein the highest initial oxidation state (i) of the Ge in the oxide is +4.

16. The method according to claim 1, wherein the method is an atomic layer deposition (ALD) method.

17. The method according to claim 1, wherein the layered doped hafnium zirconium oxide structure is formed without any intervening vacuum break.

18. The method according to claim 1, wherein the dopant precursor comprises a dopant element selected from the group consisting of Mn, Bi, Sr, B, N, Li, V, S, Sc, P, N, Ni, Ga, Mg, Cr, Sn, Sb, La, Y, Mo, and Al.

19. The method according to claim 1, wherein the layered doped hafnium zirconium oxide structure is characterized by having a thickness of at least 2.0 nm to at most 30.0 nm.

20. A system comprising:
a reaction chamber constructed and arranged to hold a substrate;
a hafnium precursor vessel constructed and arranged to contain and evaporate one or more hafnium precursor;
a zirconium precursor vessel constructed and arranged to contain and evaporate one or more zirconium precursor;
an oxygen reactant vessel constructed and arranged to contain and evaporate an oxygen reactant;
a dopant precursor vessel constructed and arranged to contain and evaporate a dopant precursor;
a metal precursor vessel constructed and arranged to contain and evaporate a metal precursor; and
a controller,
wherein the controller is configured to control the flow of the hafnium precursor, the zirconium precursor, the oxygen reactant, the dopant precursor, and the metal precursor, into the reaction chamber, thereby forming a layered doped hafnium zirconium oxide structure on the substrate.
